(19) United States
(12) Patent Application Publication
(10) Pub. No.: US 2021/0296520 A1
(43) Pub. Date: Sep. 23, 2021

(54) ELECTRICALLY CONDUCTIVE ADHESIVES FOR SOLAR CELL MODULES

(71) Applicant: SUNPOWER CORPORATION, San Jose, CA (US)

(72) Inventors: Ruihua LI, Cupertino, CA (US); Yafu LIN, San Jose, CA (US)

(73) Assignee: SUNPOWER CORPORATION, San Jose, CA (US)

(21) Appl. No.: 16/827,124

(22) Filed: Mar. 23, 2020

(51) Int. Cl. H01L 31/05

(52) U.S. Cl. CPC H01L 31/0516

(57) ABSTRACT

A solar module includes at least one first solar cell and at least one second solar cell, each including: a substrate including a first semiconductor region of a first conductivity type and a second semiconductor region of a second conductivity type different from the first conductivity type; a first metallization pattern providing electrical contact to the first semiconductor region of the first conductivity type; and a second metallization pattern providing electrical contact to the second semiconductor region of the second conductivity type; and an electrically conductive adhesive material disposed between at least a portion of the first metallization pattern of the first solar cell and the second metallization pattern of the second solar cell, wherein the electrically conductive adhesive material has a glass transition temperature (T_{g}) greater than 70° C. and an elastic modulus less than 3500 MPa.

### FIELD

This disclosure relates generally to an electrically conductive adhesive for solar cell modules and methods of applying the electrically conductive adhesive.

### BACKGROUND

The photovoltaic (PV) industry can employ front-to-back series interconnect ribbons to make interconnections between solar cells. However, the front-to-back series interconnect ribbons can block the incident sunshine and reduce the active illuminated area on the solar cells. Shingle interconnections can alternatively offer high packing densities of solar cell modules. Shingled solar cell modules can include solar cells conductively connected to each other in a shingled arrangement to form supercells, which can be arranged to efficiently utilize the area of an installation of the solar cell modules, reduce series resistance, and increase solar cell module efficiency. Electrically conductive adhesives (ECAs) can be used to directly interconnect the strip-like solar cells, which eliminate the interconnectors' ohmic losses. Stripe-like solar cells additionally reduce the overall ohmic losses of the solar cell string by lowering cell currents.

ECAs play an important role in shingled solar cell modules as well as interconnections to other conductive elements, such as wiring. The ECA not only interconnects the shingled solar cells (or connects the solar cells to other conductive wiring), but its material properties also affect the performance and reliability of the shingled solar cell modules. A “soft” (i.e. low modulus of elasticity) ECA can help increase the durability of the shingled solar cell modules under stress, for example a snow load, by cushioning a lower shingled solar cell during a snow load stress scenario. Thus, a shingled solar cell module connected via softer ECAs can yield fewer solar cell cracks and damage as compared to a solar cell module connected via a harder ECA since the soft ECA helps absorb the force applied from an upper solar cell down onto the lower solar cell at the interconnection location. Furthermore, another property of the ECA, the glass transition temperature (T_{g}), can impact the performance of the ECA when applied to the shingled solar cell modules. Namely, an ECA with a high T_{g} can have a smaller coefficient of thermal expansion (CTE) within the module operation temperature range, which creates less stress during thermal cycling between varying components of different materials in contact with the ECA. That is, a shear force can be applied to the ECA at the interconnection location due to a temperature-induced change in shape of connected solar cell strips & ECAs and glass & backsheet, thus shifting the location of the solar cell strips relative to each other, and therefore the ECA connecting the solar cell modules.

Thus, a solar cell module including an ECA with a low modulus of elasticity, high T_{g}, and low CTE is desired.

### SUMMARY

An ECA for connecting solar cells are described herein.

In one exemplary aspect, a solar module includes a supercell comprising a plurality of solar cell strips arranged such that adjacent edges of adjacent solar cell strips overlap and are conductively bonded to each other in series via an electrically conductive material, wherein the electrically conductive material has a glass transition temperature (T_{g}) greater than 70° C. and an elastic modulus less than 3500 MPa.

In one exemplary aspect, a solar module includes at least one first solar cell and at least one second solar cell, each including: a substrate including a first semiconductor region of a first conductivity type and a second semiconductor region of a second conductivity type different from the first conductivity type; a first metallization pattern providing electrical contact to the first semiconductor region of the first conductivity type; and a second metallization pattern providing electrical contact to the second semiconductor region of the second conductivity type; an electrically conductive adhesive material disposed between at least a portion of the first metallization pattern of the first solar cell and the second metallization pattern of the second solar cell, wherein the electrically conductive adhesive material has a glass transition temperature (T_{g}) greater than 70° C. and an elastic modulus less than 3500 MPa.

In one exemplary aspect, the first metallization pattern includes a first rear surface, the second metallization pattern includes a front surface contact pad attached to an electrically coupled with the first electrical connection of the second solar cell; and the front and rear contact pads are electrically connected via the electrically conductive adhesive material.

In one exemplary aspect, the elastic modulus of the electrically conductive adhesive material is less than 1500 MPa.

In one exemplary aspect, the elastic modulus of the electrically conductive adhesive material is less than 1000 MPa.

In one exemplary aspect, the elastic modulus of the electrically conductive adhesive material is less than 600 MPa.

In one exemplary aspect, the T_{g} of the electrically conductive adhesive material is greater than 80° C.

In one exemplary aspect, the T_{g} of the electrically conductive adhesive material is greater than 85° C.

In one exemplary aspect, the elastic modulus of the electrically conductive adhesive material is less than 600 MPa and the T_{g} of the electrically conductive adhesive material is greater than 85° C.

In one exemplary aspect, the at least one first solar cell and the at least one second solar cell are arranged in a shingled configuration.

In one exemplary aspect, the at least one first solar cell and the at least one second solar cell are metal wrap-through solar cells.

In one exemplary aspect, a method of fabricating a solar cell module, includes: providing at least one first solar cell and at least one second solar cell, each including a substrate including a first semiconductor region of a first conductivity type and a second semiconductor region of a second conductivity type different from the first conductivity type, a first metallization pattern providing electrical contact to the first semiconductor region of the first conductivity type, and a second metallization pattern providing electrical contact to the second semiconductor region of the second conductivity type; arranging the first edge of the at least one first solar cell to overlap with the second edge of the at least one second solar cell, the first edge of the at least one first solar cell being disposed over top the second edge of the at least one second solar cell; and connecting, via an electrically conductive adhesive material, the first metallization pattern of the first solar cell and the second metallization pattern of the second solar cell, the electrically conductive adhesive material forming an electrical connection between the first metallization pattern of the first solar cell and the second metallization pattern, the electrically conductive adhesive material having a glass transition temperature (T_{g}) greater than 70° C. and an elastic modulus less than 3500 MPa.

In one exemplary aspect, the elastic modulus of the electrically conductive adhesive material is less than 1500 MPa.

In one exemplary aspect, the elastic modulus of the electrically conductive adhesive material is less than 1000 MPa.

In one exemplary aspect, the elastic modulus of the electrically conductive adhesive material is less than 600 MPa.

In one exemplary aspect, the T_{g} of the electrically conductive adhesive material is greater than 80° C.

In one exemplary aspect, the T_{g} of the electrically conductive adhesive material is greater than 85° C.

In one exemplary aspect, the elastic modulus of the electrically conductive adhesive material is less than 600 MPa and the T_{g} of the electrically conductive adhesive material is greater than 85° C.

In one exemplary aspect, the at least one first solar cell and the at least one second solar cell are arranged in a shingled configuration.

In one exemplary aspect, a material of the bottom contact pad and the top contact pad is silver, gold, platinum, or copper.

In one exemplary aspect, the at least one first solar cell and the at least one second solar cell are metal wrap-through solar cells

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein:

FIG. 1A illustrates a module including a first solar cell and a second solar cell, according to an exemplary aspect of the present disclosure.

FIG. 1B illustrates a shingled module including a first solar cell strip and a second solar cell strip, according to an exemplary aspect of the present disclosure.

FIG. 1C illustrates a portion of a super cell including shingled solar cell strips, according to an exemplary aspect of the present disclosure.

FIG. 1D illustrates a first solar cell strip electrically connected to an external load, according to an aspect of the present disclosure.

FIG. 2A illustrates induced stress at a connection structure due to an applied load, according to an exemplary aspect of the present disclosure.

FIG. 2B illustrates an ECA with a low modulus, according to an exemplary aspect of the present disclosure.

FIG. 2C illustrates an ECA with a high T_{g}, according to an exemplary aspect of the present disclosure.

FIG. 3A shows electroluminescence images of solar cell modules during a snow load test, according to an exemplary aspect of the present disclosure.

FIG. 3B shows electroluminescence images of solar cell modules during a snow load test, according to an exemplary aspect of the present disclosure.

### DETAILED DESCRIPTION

The following detailed description should be read with reference to the drawings, in which identical reference numbers refer to like elements throughout the different figures. The drawings, which are not necessarily to scale, depict exemplary aspects and are not intended to limit the scope of this disclosure. The detailed description illustrates by way of example, not by way of limitation, the exemplary principles that enable one skilled in the art to make and use devices and methods defined by the claims. Of course, numerous variations and permutations of the features described herein are embraced by this disclosure, and the appended claims, as one of ordinary skill in the art would recognize.

As used in this specification and the appended claims, the singular forms “a,” “an,” and “the” include plural referents unless the context clearly indicates otherwise. Also, the term “parallel” is intended to mean “parallel or substantially parallel” and to encompass minor deviations from parallel geometries rather than to require that any parallel arrangements described herein be exactly parallel. The term “perpendicular” is intended to mean “perpendicular or substantially perpendicular” and to encompass minor deviations from perpendicular geometries rather than to require that any perpendicular arrangement described herein be exactly perpendicular. The term “square” is intended to mean “square or substantially square” and to encompass minor deviations from square shapes, for example substantially square shapes having chamfered (e.g., rounded or otherwise truncated) corners. The term “rectangular” is intended to mean “rectangular or substantially rectangular” and to encompass minor deviations from rectangular shapes, for example substantially rectangular shapes having chamfered (e.g., rounded or otherwise truncated) corners.

This specification describes high efficiency hybrid dense solar cells (“HDSC”), HDSC interconnects, and series-connected HDSC strings or “hypercells,” as well as front and rear surface metallization patterns and associated interconnects for solar cells that may be used in such arrangements. This specification also describes methods for manufacturing HDSCs, HDSC interconnects and strings or hypercells. The solar cell modules may be advantageously employed under “one sun” (non-concentrating) illumination, and may have physical dimensions and electrical specifications allowing them to be substituted for crystalline silicon solar cell modules.

The specification also describes “electrical connection” between two or more objects or that two or more elements may be in “electrical connection.” Electrical connection is established between two or more conductive material such that electrons can substantially freely flow through the materials in a given direction when subjected to an electrical load. In other words, two elements are considered to be in electrical connection when an electrical current can flow readily therethrough.

A low modulus of elasticity and low glass transition temperature (T_{g}) electrically conductive adhesive (ECA) can help the snow load performance of a shingled solar cell module. It may be appreciated that hereinafter, “modulus of elasticity” may be referred to as simply “modulus.” However, low Tg (e.g. T_{g}<85° C.) ECAs can have a higher coefficient of thermal expansion (CTE) (e.g. −40° C. to 85° C.), which can induce myriad stresses during thermal cycling. High T_{g} and high modulus ECAs can have better thermal cycling performance, but a concomitantly higher modulus can yield poorer performance in reducing failures during load between solar cells, such as in a snow load test. To resolve this issue, a low modulus and high T_{g} ECA are described herein.

The ECA described herein can be used in a shingled solar cell arrangement. The ECA not only can interconnect the strip-like solar cells but also can improve the reliability of the shingled solar cell arrangement during environmentally relevant tests, such as snow load and thermal cycling performance tests, and in their realized application.

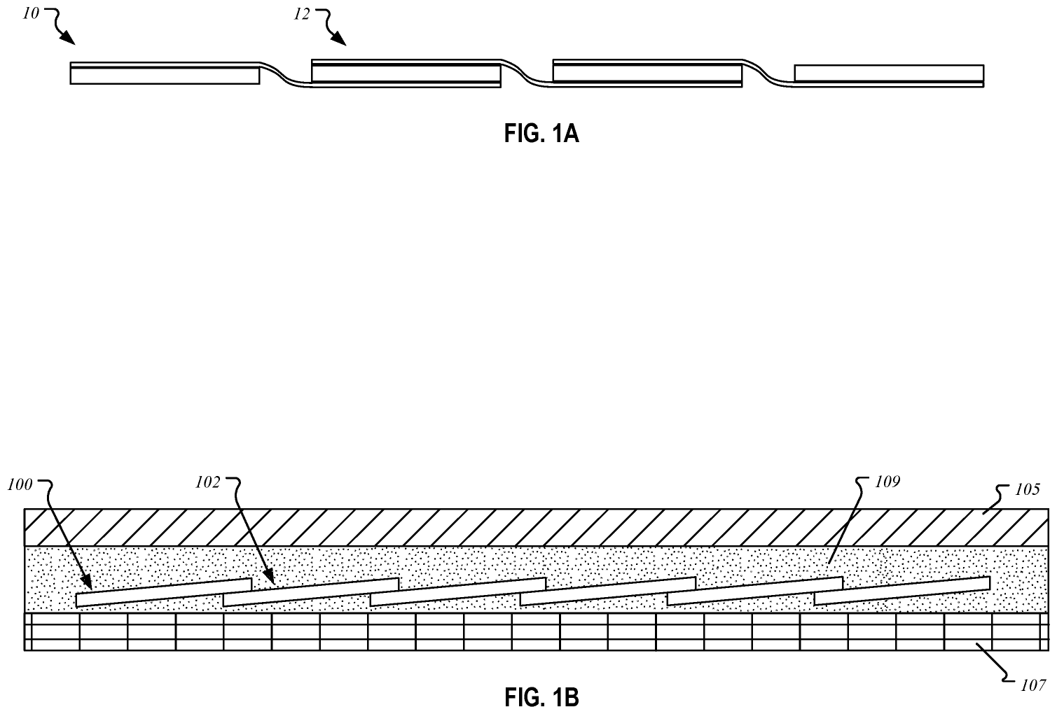

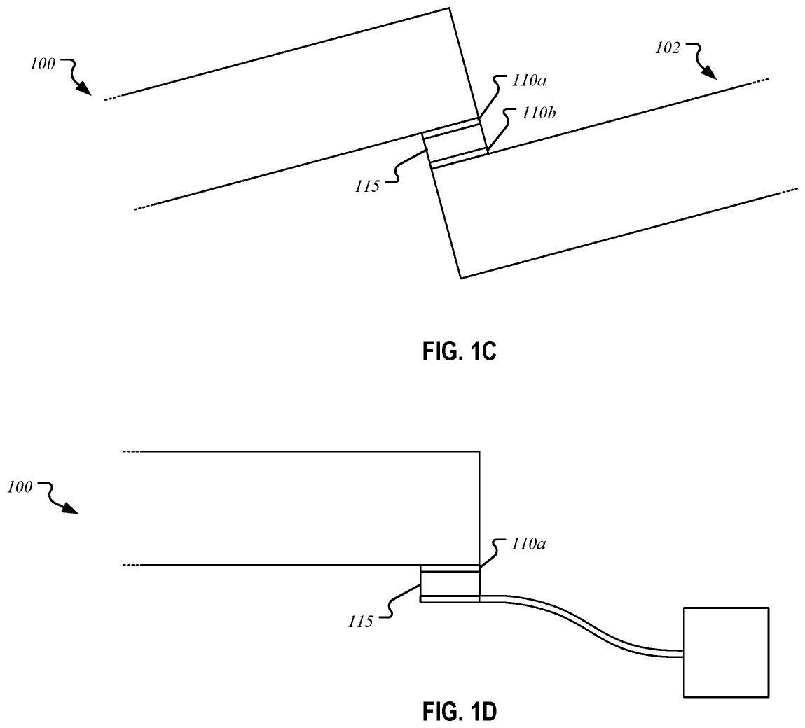

FIG. 1A illustrates a module including a first solar cell 10 and a second solar cell 12 connected via a conductor, according to an exemplary aspect of the present disclosure. It may be appreciated that the supercell may include more than the first and second solar cells 10, 12. For example, the module can include 3, 100, or more solar cell strips in order to cover a predetermined area. In an aspect, the first solar cell 10 and the second solar cell strip 12 can be electrically connected. For example, the first solar cell 10 can be electrically connected to the second solar cell 12 via a ribbon connection, wherein an electrical connection can be made from a top surface of the first solar cell 10 to a bottom surface of the second solar cell 12. The first and second solar cells 10, 12 can include a semiconductor diode structure and electrical contacts to the semiconductor diode structure by which electric current generated in the module, when illuminated by light, can be provided to an external load (FIG. 1D). As previously described, a portion of the ribbon connection disposed above the top surface of the first solar cell 10 can block a portion of the incident light illuminating the first solar cell 10. This can reduce the potential efficiency of the first solar cell 10, and any additional solar cells in the module that include a ribbon connection covering top surfaces of the solar cells. Thus, an alternative connection between the first and second solar cells 10, 12 can be utilized to increase the potential efficiency.

FIG. 1B illustrates a cross-sectional view of a string of series-connected solar cells arranged in a shingled arrangement with the ends of adjacent solar cells overlapping and electrically connected to form a super cell, according to an exemplary aspect of the present disclosure. In an embodiment, the module can include a glass sheet 105, a backsheet 107, and an encapsulant 109, and shingled solar cell strips disposed between the glass sheet 105 and the backsheet 107 inside the encapsulant 109. In some embodiments, the backsheet 107 can be another of the glass sheet 105. In some embodiments, the encapsulant 109 is optional. The first solar cell strip 100 and the second solar cell strip 102 can include a semiconductor diode structure and electrical contacts to the semiconductor diode structure by which electric current generated in the first solar cell strip 100 and the second solar cell strip 102 when illuminated by light may be provided to an external load. The backsheet 107 (or second panel of the glass sheet 105) can be, for example, disposed under the solar cell strips 100, 102. The encapsulant 109 can be transparent and configured to seal the solar cell strips 100, 102 in between the glass sheet 105 and the backsheet (or glass) 107.

FIG. 1C illustrates a portion of the super cell including shingled solar cell strips, such as a first solar cell strip 100 and a second solar cell strip 102, according to an exemplary aspect of the present disclosure.

In one aspect, each solar cell strip can be a crystalline silicon solar cell having front (sun side) surface and rear (shaded side) surface metallization patterns providing electrical contact to opposite sides of an n-p junction, the front surface metallization pattern can be disposed on a semiconductor layer of n-type conductivity, and the rear surface metallization pattern can be disposed on a semiconductor layer of p-type conductivity. However, any other suitable solar cells employing any other suitable material system, diode structure, physical dimensions, or electrical contact arrangement may be used instead of or in addition to solar cells in the solar modules described in this specification. For example, the front (sun side) surface metallization pattern may be disposed on a semiconductor layer of p-type conductivity, and the rear (shaded side) surface metallization pattern disposed on a semiconductor layer of n-type conductivity. In another example, the solar cells can utilize a metal wrap-through (MWT) design to extract the current from the front surface. That is, the metal that runs along the front surface of the solar cell to extract the electrical current can be routed to the rear surface of the solar cell by fabricating holes or “vias” through which metal can be deposited and formed inside thereof and fired into the solar cell to allow generated current to be extracted.

Adjacent solar cell strips of a super cell can be conductively bonded to each other in the region in which they overlap by an electrically conducting bonding material that electrically connects the front surface metallization pattern of one solar cell to the rear surface metallization pattern of the adjacent solar cell as described herein.

The first solar cell strip 100 and the second solar cell strip 102 can be electrically connected in a shingled arrangement. The first solar cell strip 100 and the second solar cell strip 102 can be electrically connected in series in a string wherein a portion of a bottom surface of the first solar cell strip 100, for example along an edge of the first solar cell strip 100, can at least partially overlap a portion of a top surface of the second solar cell strip 102, for example along an edge of the second solar cell strip 102. As shown in FIG. 1C, the edges can, for example, be along the longer dimension of the solar cell strips 100, 102. Between the overlapping portions can be disposed a first contact pad 110a, an electrically conductive adhesive (ECA) 115, and a second contact pad 110b configured to electrically connect the first solar cell strip 100 to the second solar cell strip 102. The first contact pad 110a can be attached to the bottom surface of the first solar cell strip 100 and the second contact pad 110b can be attached to the top surface of the second solar cell strip 102. The ECA 115 can be applied to attach the first contact pad 110a to the second contact pad 110b. That is, the ECA 115 can be disposed between the first contact pad 110a and the second contact pad 110b. The first and second contact pads 110a, 110b can be electrically coupled to wiring and components in respective solar cell strips 100, 102 via electrical connections disposed on the top and bottom surfaces of the solar cell strips 100, 102. For example, the electrical connections can be disposed along the edges of the solar cell strips 100, 102 to facilitate arrangement in a shingled configuration. For example, a direction of the shingling (i.e. a direction along which additional solar cell strips are added) can be along the string direction, or perpendicular to the long edges of the solar cell strips 100, 102. A material of the first and second contact pads 110a, 110b can be a conductive metal and include, but is not limited to, silver, copper, gold, platinum, or any combination thereof.

The first contact pad 110a and the second contact pad 110b need not be a significantly raised feature on the surface of the solar cell strips 100, 102. Rather, the first contact pad 110a and the second contact pad 110b (and metallization fingers) can be printed on the surface and essentially appear planar. The thickness of the ECA 115 bond between adjacent overlapping solar cell strips formed by the ECA 115 bonding material, measured perpendicularly to the front and rear surfaces of the solar cells strips 100, 102, may be, for example, less than about 0.1 mm. Such a thin bond can reduce resistive loss at the interconnection between cells, and also promote flow of heat along the super cell from any hot spot in the super cell that might develop during operation.

In an exemplary embodiment, a length of the solar cell strips 100, 102 can be, for example, 125-210 mm, a width of the solar cell strips 100, 102 can be, for example, 15-35 mm, and a thickness of the solar cell strips 100, 102 can be, for example, 0.1-0.3 mm. The overlap can be, for example, 0.5-1.5 mm of the first solar cell strip 100 over the second solar cell strip 102. A length of the first and second contact pads 110a, 110b can be, for example, 0.5-2 mm, a width of the first and second contact pads 110a, 110b can be, for example, 3-5 mm, and a thickness of the first and second contact pads 110a, 110b can be, for example, 0.05-0.2 mm. The amount of applied ECA 115 can be 0.02 to 0.1 mm thick at a predetermined temperature. For example, the solar cell strips can be fabricated at the predetermined temperature, wherein the predetermined temperature is 150° C. The first and second contact pads 110a, 110b and the ECA 115, as a connection structure having a layered, sandwich arrangement, can be formed as a single long strip along the edges of the first and second solar cell strips 100, 102, or at a plurality of locations along the edge as a plurality of separate connection structures. Notably, the single long strip may provide increased surface area to spread the weight of the first solar cell strip 100 acting on the second solar cell strip 102. On the other hand, the effect of the mismatch in CTE can be lessened with the use of the plurality of separate connection structures. The amount of overlap may be determined based on various factors including, but not limited to, the total length of the overlapping solar cell strips 100, 102, the weight of the solar cell strips 100, 102, the thickness of the solar cell strips 100, 102, the materials used to connect the solar cell strips 100, 102, the amount of flexibility required in the fully assembled module, the shape of the overlapping solar cell strip 100, 102 edges (e.g. linear edges, non-linear, or “wavy” edges, etc.), a desired amount of sunlight exposure for top surfaces, and the like.

It may be appreciated that the solar cell module can include additional solar cell strips connected in the string. Each solar cell strip need not be the same size or shape, for example in order to cover a non-rectangular predetermined area. Furthermore, the solar cell module can include a plurality of the electrically connected strings, the plurality of strings being disposed adjacent to each other along the shingling direction.

FIG. 1D illustrates the first solar cell strip 100 electrically connected to an external load 120, according to an aspect of the present disclosure. Notably, the external load 120 can be connected to any arrangement of the solar cell strips 100, 102 using the ECA 115. The ECA 115 can allow for less of a coefficient of thermal expansion (CTE) mismatch between wiring used to electrically couple components and the ECA 115.

It may be appreciated that the ECA 115 can be applied to other solar cell applications. For example, the ECA 115 can be used in a MWT solar cell and printed as an adhesive design on the conductive backsheet 107 through which interconnections can be formed.

As previously described, the ECA 115 with a low modulus at low temperature can help during the snow loading test. Power loss after the snow load test is mainly caused by cracking of individual cells in the solar cell strips 100, 102 due to applied load from one solar cell strip (e.g. the first solar cell strip 100) on top of another adjacent solar cell strip (e.g. the second solar cell strip 102). The softer ECA 115 can protect and cushion the shingled solar cell strips 100, 102 during the snow load test. Thus, shingled solar cell modules made from the softer ECA 115 will result in less cell cracks than a module made from a harder ECA.

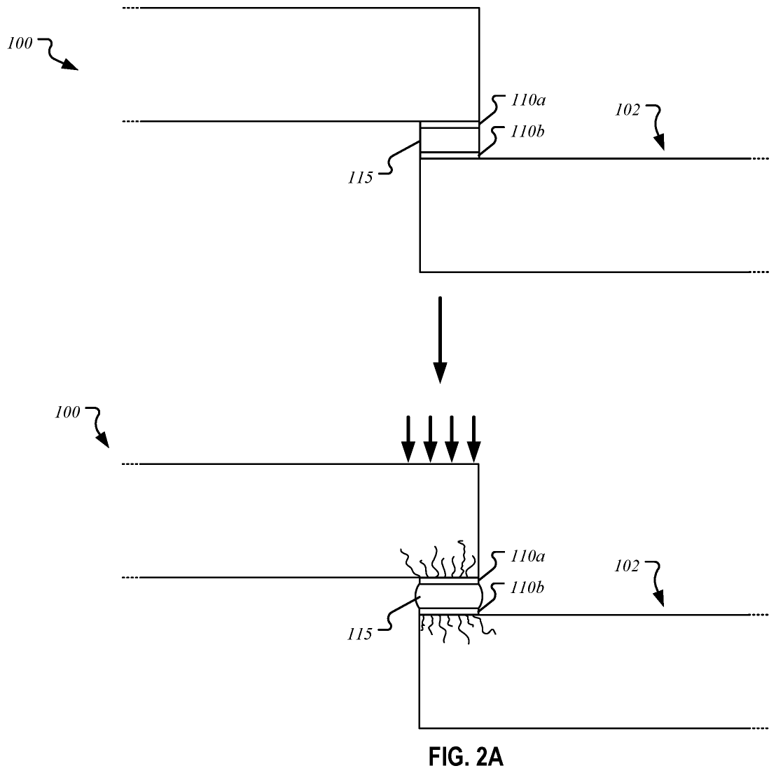

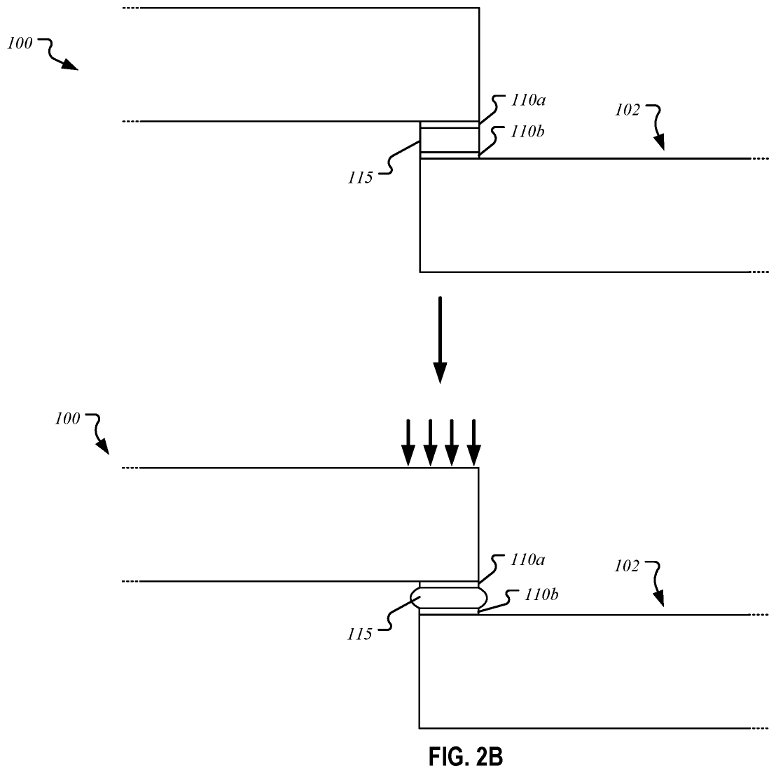

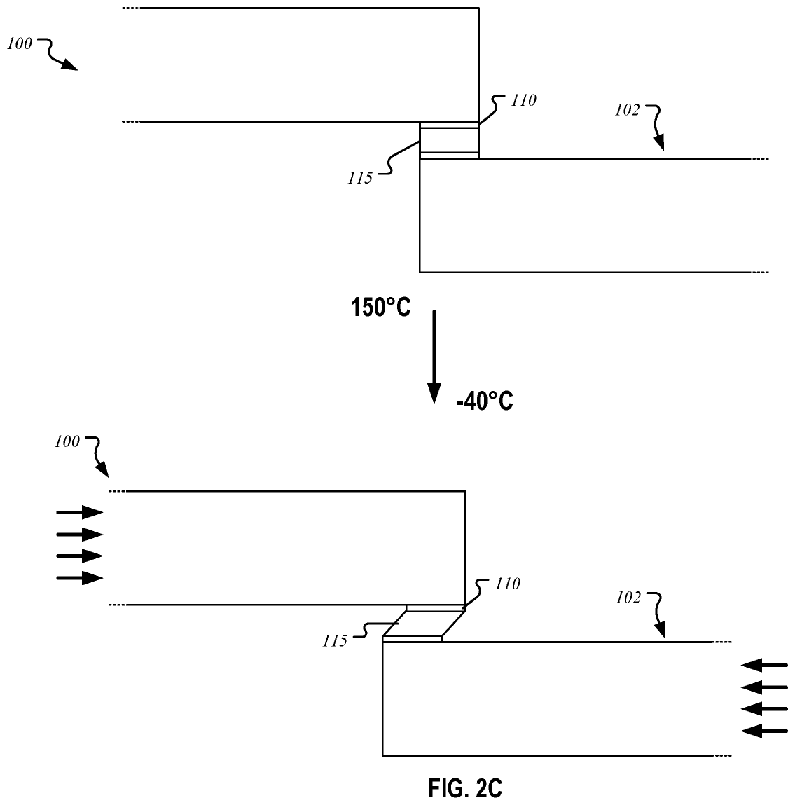

FIG. 2A illustrates induced stress at the connection structure due to an applied load, according to an exemplary aspect of the present disclosure. In an exemplary aspect, the first solar cell strip 100 can be arranged on top of the second solar cell strip 102. The applied load can cause cracking of solar cells in both the first solar cell strip 100 and the second solar cell strip 102 due to the applied downward force at the connection structure without the ECA 115 having a sufficiently low modulus.

As previously described, during thermal cycling (e.g. −40° C. to 85° C.), all of the materials (e.g. solar cell wafers, the ECA 115, the glass sheet 105, the backsheet 107, the encapsulant 109, etc.) can reduce in volume (at low temperature) and expand in volume (at high temperature). There can be a subsequent CTE mismatch between different materials. Different expansion or contraction rate between different materials can induce stress and cause failure. Solar cells (e.g. silicon wafers) can have a low CTE. However, the ECA 115 can have a high CTE. The CTE mismatch can induce stress and break the connection. The ECA 115 with a high T_{g} can have a lower CTE. Thus, the resulting CTE mismatch between the solar cell strips 100, 102 and the ECA 115 is smaller. Concomitantly, the thermal cycling performance is better.

In one example, the module can be fabricated at the predetermined temperature of 150° C. and stresses can be introduced upon cooling of the components down to room temperature or lower. For example, the modules can be installed in environments where snow occurs during a winter season. Thus, it is desired that the CTE mismatch be reduced to account for a wide range of temperature cycles, such as between hot and cold seasons. A change in temperature of the environment can cause a change in the dimensions of the glass 105 and backsheet 107 of the solar cell strips 100, 102. For example, the CTE for Si can be very low and contraction of the solar cell strips 100, 102 can be considered as minimal when compared to the encapsulant 105 or backsheet 107. The displacement between the solar cell strips 100, 102 can be mainly caused by the CTE mismatch between the glass 105 and the backsheet 107. That is, the backsheet 107 can shrink more than the other components. Thus, stress can be applied laterally inwards to the solar cell strips 100, 102 and compress the solar cell strips 100, 102 towards the center of the module.

This can lead to a relative displacement, for example a lateral shifting, between the edges of the solar cell strips 100, 102 and concomitantly, between the contact pads 110a, 110b. A resulting shear can be induced at the connection structure, specifically applied to the ECA 115. If the temperature difference induces a large enough dimension change and resulting large shear force, the ECA 115 can degrade to a state of reduced conduction or complete failure of conduction. Thus, a low modulus for the ECA 115 is desired for such an event.

In one example, the change in temperature can induce a change in the dimension of the ECA 115 and the solar cell strips 100, 102 along a direction perpendicular to the plane of the solar cell strips 100, 102. For example, a decrease in temperature can cause the ECA 115 to contract in volume, leading to a narrowing of the ECA 115 between the contact pads 110a, 110b. Notably, there can also be a contraction in dimension of the glass 105 and the backsheet 107, which can further cause a pulling apart force between the solar cell strips 100, 102. The backsheet 107 can have a higher CTE and shrink more than the glass 105, which can apply stress to the solar cell strips 100, 102, and pull apart. This pull force can increase the stress applied to the contracted ECA 115 and additionally narrow the ECA 115. If the temperature difference induces a large enough volume change and resulting large pull force, the ECA 115 can be cracked or sever completely, which reduces conduction or results in complete conduction failure. Thus, a high glass transition temperature (T_{g}) for the ECA 115 is desired to reduce the CTE mismatch.

Additionally, the change in volume due to temperature changes, for example the temperature decrease, can cause a relative displacement between the solar cell strips 100, 102 laterally as well as vertically (i.e. perpendicular to the plane of the solar cell strips 100, 102). It may be appreciated that a majority of the displacement stems from the lateral forces. With the temperature decrease, a combined effect described above can result in a shearing of the ECA 115, as well as a contraction of the ECA 115, further increasing the potential of conduction loss.

FIG. 2B illustrates the ECA 115 with a low modulus, according to an exemplary aspect of the present disclosure. In an exemplary aspect, the modulus of the ECA 115 is sufficiently low enough that the applied load on the first solar cell strip 100 is cushioned by the low modulus ECA 115 and does not crack the solar cell strips. Therefore, structural integrity of the solar cells (and thus optimal operating efficiency) is maintained through the load test.

FIG. 2C illustrates the ECA 115 with a high T_{g}, according to an exemplary aspect of the present disclosure. In an exemplary aspect, in addition to the low modulus, the T_{g} of the ECA 115 is sufficiently high enough that the change in temperature causing the dimension change between the solar cell strips 100, 102 and the ECA 115 does not result in failure of the ECA 115 due to the applied shear force or the applied pull force. Instead, the CTE mismatch is low enough that the ECA 115 flexes with the change in relative positioning of the solar cell strips 100, 102 and thus the contact pads 110a, 110b. Therefore, conductivity of the ECA 115 is maintained through the thermal cycling. The T_{g} of the ECA 115 can be greater than, for example, 70° C., or 80° C. or preferably, 85° C. It may be appreciated that the ECA 115 can be used to connect more than just shingled solar cells, for example solar cells connected via a ribbon connection or solar cells connected to external loads.

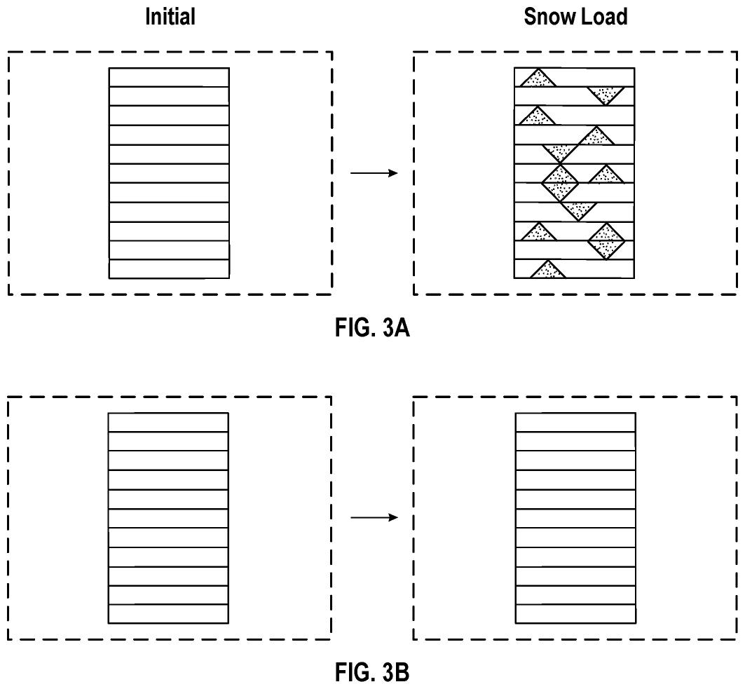

FIG. 3A shows schematics of solar cell modules during the snow load test, according to an exemplary aspect of the present disclosure. In an exemplary aspect, the left schematic shows a first solar cell module 300 without an applied snow load. Notably, no force is applied to the first solar cell module 300 as indicated. For the ECA 115 having a high (i.e. stiff) modulus, the applied snow load yields the right schematic of the first solar cell module 300 with damaged solar cells due to the ECA 115 modulus not being sufficiently low to cushion the applied snow load.

FIG. 3B shows schematics of solar cell modules during the snow load test, according to an exemplary aspect of the present disclosure. In an exemplary aspect, the left schematic shows a second solar cell module 312 without an applied snow load. Notably, no force is applied to the second solar cell module 312 as indicated. For the ECA 115 having a low (i.e. soft) modulus, the applied snow load yields the right schematic of the second solar cell module 312 showing the second solar cell module 312 with undamaged solar cells due to the ECA 115 modulus being sufficiently low to cushion the applied snow load. The modulus of the ECA 115 at 25° C. can be, for example, <3500 MPa, or <1500 MPa, or <1160 MPa, or <1000 MPa, or <800 MPa, or preferably, <600 MPa.

In some embodiments, the elastic modulus of the ECA 115 can be dependent on temperature. For example, the modulus at −40° C. can have a range of 5-10 GPa. In another example, the modulus at 45° C. can have a range of 0.5-3 GPa. The aforementioned T_{g} and modulus can be measured, for example, by dynamic mechanical analysis (DMA) using an ASTM D7028 testing method. In one example, DMA can characterize the mechanical response of viscoelastic materials under conditions of an oscillatory force. In an embodiment, the properties of the ECA 115 are as follows: 130C>Tg>85C, modulus <1500 MPa (at 25° C.). Furthermore, the properties of the ECA 115 can be dependent on a lifetime of the ECA 115. That is, in some adhesives, the performance of the adhesive can degrade the longer it is used in the device. The thermal cycling and exposure to the environment can degrade the performance, for instance. Therefore, it is desired that the properties of the ECA 115 remain within a predetermined deviation for a predetermined length of time. In one example, the properties of the ECA 115 can remain within a 5% deviation after a predetermined length of time of one year. In another example, the properties of the ECA 115 can remain within a 20% deviation after a predetermined length of time of 5 years. The predetermined length of time can be measured starting from, for example, first utilization and exposure in the field. Alternatively, the predetermined length of time can be measured starting from, for example, first application during manufacture.

Obviously, numerous modifications and variations of the present invention are possible in light of the above teachings. It is therefore to be understood that within the scope of the appended claims, the invention may be practiced otherwise than as specifically described herein.

1. A solar module, comprising:
a supercell comprising a plurality of solar cell strips arranged such that adjacent edges of adjacent solar cell strips overlap and are conductively bonded to each other in series via an electrically conductive material, wherein
the electrically conductive material has a glass transition temperature (T_{g}) greater than 70° C. and an elastic modulus less than 3500 MPa.

2. A solar module, comprising:
at least one first solar cell and at least one second solar cell, each including:
a substrate including a first semiconductor region of a first conductivity type and a second semiconductor region of a second conductivity type different from the first conductivity type;
a first metallization pattern providing electrical contact to the first semiconductor region of the first conductivity type; and
a second metallization pattern providing electrical contact to the second semiconductor region of the second conductivity type; and
an electrically conductive adhesive material disposed between at least a portion of the first metallization pattern of the first solar cell and the second metallization pattern of the second solar cell, wherein
the electrically conductive adhesive material has a glass transition temperature (T_{g}) greater than 75° C. and an elastic modulus less than 3500 MPa.

3. The module of claim 2, wherein
the first metallization pattern of the first solar cell includes a rear surface contact pad attached to and electrically coupled with a first electrical connection of the first solar cell,
the second metallization pattern of the second solar cell includes a front surface contact pad attached to and electrically coupled with a first electrical connection of the second solar cell, and
the front and rear surface contact pads are electrically connected via the electrically conductive adhesive material.

4. The module of claim 2, wherein the elastic modulus of the electrically conductive adhesive material is less than 1500 MPa.

5. The module of claim 2, wherein the elastic modulus of the electrically conductive adhesive material is less than 600 MPa.

6. The module of claim 2, wherein the T_{g} of the electrically conductive adhesive material is greater than 80° C.

7. The module of claim 2, wherein the T_{g} of the electrically conductive adhesive material is greater than 85° C.

8. The module of claim 2, wherein the elastic modulus of the electrically conductive adhesive material is less than 600 MPa and the T_{g} of the electrically conductive adhesive material is greater than 85° C.

9. The module of claim 2, wherein the at least one first solar cell and the at least one second solar cell are arranged in a shingled configuration.

10. The module of claim 2, wherein the at least one first solar cell and the at least one second solar cell are metal wrap-through solar cells.

11-20. (canceled)

21. The module of claim 2, wherein the elastic modulus of the electrically conductive adhesive material is less than 1500 MPa and the T_{g} of the electrically conductive adhesive material is greater than 80° C.

22. The module of claim 2, wherein the elastic modulus of the electrically conductive adhesive material is less than 1500 MPa and the T_{g} of the electrically conductive adhesive material is greater than 85° C.

23. The module of claim 2, wherein the elastic modulus of the electrically conductive adhesive material is less than 1000 MPa and the T_{g} of the electrically conductive adhesive material is greater than 80° C.

24. The module of claim 2, wherein the elastic modulus of the electrically conductive adhesive material is less than 1000 MPa and the T_{g} of the electrically conductive adhesive material is greater than 85° C.

25. The module of claim 2, wherein the elastic modulus of the electrically conductive adhesive material is less than 800 MPa and the T_{g} of the electrically conductive adhesive material is greater than 80° C.

26. The module of claim 2, wherein the elastic modulus of the electrically conductive adhesive material is less than 800 MPa and the T_{g} of the electrically conductive adhesive material is greater than 85° C.

27. The module of claim 2, wherein the elastic modulus of the electrically conductive adhesive material is less than 600 MPa and the T_{g} of the electrically conductive adhesive material is greater than 80° C.

28. The module of claim 2, wherein a material of the rear surface contact pad and the front surface contact pad is silver, gold platinum, or copper.
